(19) United States
(12) Patent Application Publication
(10) Pub. No.: US 2010/0052503 A1
(43) Pub. Date: Mar. 4, 2010

(54) ELECTRO-OPTICAL DEVICE, METHOD OF MANUFACTURING ELECTRO-OPTICAL DEVICE, AND ELECTRONIC APPARATUS

(75) Inventor: Takefumi FUKAGAWA, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/508,967

(22) Filed: Jul. 24, 2009

(30) Foreign Application Priority Data
Aug. 28, 2008 (JP) 2008-219265

(51) Int. Cl. H05B 33/04; B32B 37/24

(52) U.S. Cl. 313/483; 156/280

(57) ABSTRACT

Provided is an electro-optical device including: a pair of substrates which is held to face each other with a predetermined gap therebetween; and an electro-optical material interposed between the pair of substrates, wherein a hard coat layer is formed on surfaces of the pair of substrates opposite to the electro-optical material.

### BACKGROUND

1. Technical Field

The present invention relates to an electro-optical device, a method of manufacturing the electro-optical device, and an electronic apparatus.

2. Related Art

An electro-optical device including an electro-optical material sandwiched between a pair of substrates, such as an organic electroluminescence display device (hereinafter, referred to as an organic EL devices), has been employed in a display unit in mobile telephones or the like due to their light weight and thinness. In such cases, in order to make the electro-optical device even thinner, the above-described substrates are generally subjected to a polishing process or the like. In order to suppress the reduction of strength due to such a process, a method of improving the strength of the electro-optical device in polarization plates attached to the surfaces of the substrates after polishing has been suggested (for example, see JP-A-2004-46115).

However, in the above-described method, the overall thickness of the electro-optical device is increased. In addition, there is only a small impact on cracks which may occur when the electro-optical device is manufactured. In addition, there can be obtained no effect for improving the strength of the side end of the electro-optical device.

### SUMMARY

The invention is contrived in order to solve at least a portion of the problems, and the following aspects or application examples can be realized.

According to an aspect of the invention, there is provided an electro-optical device including: a pair of substrates which is held to face each other with a predetermined gap therebetween; and an electro-optical material interposed between the pair of substrates. A hard coat layer is formed on the surfaces of the pair of substrates opposite to the electro-optical material.

By such a configuration, cracks or the like which may occur in the pair of substrates before the forming of the hard coat layer can be buried by the hard coat layer. Accordingly, it is possible to improve the strength of the electro-optical device and to improve reliability or the like.

In the above-described electro-optical device, the electro-optical device further includes a seal material interposed between the pair of substrates which holds the pair of substrates. The hard coat layer is formed on the end surfaces of the pair of substrates and on the surfaces of the seal material opposite to the electro-optical material.

By such a configuration, by forming the hard coat layer, it is possible to enhance the end surfaces of the substrate which have a higher probability of cracks or the like occurring. Accordingly, it is possible to further improve the strength of the electro-optical device.

In the above-described electro-optical device, the thickness of the hard coat layer is 5 μm or more and 50 μm or less.

In order to fill the cracks or the like, the thickness of the hard coat layer needs to be at least 5 μm. If the hard coat layer is extremely thick, the thickness of the electro-optical device is increased. Accordingly, by such a configuration, it is possible to achieve both a reduction in the thickness and an improvement in the strength of the electro-optical device.

In the above-described electro-optical device, transmissivity of the hard coat layer is 85% or more.

By such a configuration, it is possible to improve the strength of the electro-optical device without deteriorating the display quality. In addition, the transmissivity mentioned above refers to the transmissivity of visible light.

In the above-described electro-optical device, transparent resin particles, which have a refractive index lower than that of a constituent material of the hard coat layer, are mixed in the hard coat layer.

By such a configuration, it is possible to prevent surface reflection and to improve display quality.

In the above-described electro-optical device, the thickness of the electro-optical device, excluding the hard coat layer, is 50 μm to 1000 μm.

By such a configuration, it is possible to obtain an electro-optical device which is sufficiently thin even when the thickness of the hard coat layer is added.

In the above-described electro-optical device, the electro-optical material is an organic electroluminescence material.

By such a configuration, it is possible to improve the strength of an organic electroluminescence display device.

According to another aspect of the invention, there is provided an electronic apparatus including the above-described electro-optical device in a display unit.

By such a configuration, it is possible to reduce the thickness of the display unit without deteriorating the reliability and while improving portability.

According to a still another aspect of the invention, there is provided a method of manufacturing an electro-optical device including a pair of substrates which is bonded to face each other with a predetermined gap therebetween, and an electro-optical material interposed between the pair of substrates, the method includes: forming an electro-optical panel by bonding one substrate to an opposing substrate with the electro-optical material sandwiched therebetween, reducing the thickness of the electro-optical panel by polishing a second surface opposite to the first surface of at least one of the pair of substrates, and forming a hard coat layer on the second surface of at least one of the pair of substrates.

According to such a manufacturing method, it is possible to obtain an electro-optical device where strength is improved while the increase in thickness is suppressed.

In the above-described manufacturing method, the reducing of the thickness of the electro-optical panel includes polishing the second surfaces of both of the substrates in the pair, and the forming of the hard coat layer includes forming the hard coat layers on the second surfaces of both of the substrates in the pair.

According to such a manufacturing method, it is possible to obtain an electro-optical device with further improved strength while the increase in thickness is further suppressed.

In the above-described manufacturing method, the reducing of the thickness of the electro-optical panel includes polishing the second surface such that the thickness of the electro-optical panel becomes 50 μm.

According to such a manufacturing method, it is possible to obtain an electro-optical device where the increase in thickness is minimized while the necessary strength is maintained.

In the above-described manufacturing method, the forming of the hard coat layer includes forming the hard coat layer such that the thickness of the hard coat layer becomes 5 μm or more and 50 μm or less.

According to such a manufacturing method, it is possible to improve the strength of the electro-optical device while the increase in thickness is minimized.

In the above-described manufacturing method, the manufacturing method further includes the forming of the hard coat layer on the end surfaces of the electro-optical panel.

According to such a manufacturing method, since all the surfaces of the electro-optical device can be covered by the hard coat layer, it is possible to further improve strength.

In the above-described manufacturing method, the forming of the hard coat layer includes forming a hard coat layer in which transparent resin particles, which have a refractive index lower than that of a constituent material of the hard coat layer, are mixed.

According to such a manufacturing method, it is possible to obtain an electro-optical device with improved strength and display quality.

### BRIEF DESCRIPTION OF THE DRAWINGS

The invention will be described with reference to the accompanying drawings, wherein like numbers reference like elements.

FIG. 1 is an equivalent circuit diagram of various elements, wires and the like of an organic EL device according to a first embodiment of the invention.

FIG. 2 is a schematic cross-sectional view of an organic EL panel as an electro-optical panel included in the organic EL device according to the first embodiment of the invention.

FIG. 3 is a schematic cross-sectional view of the organic EL device according to the first embodiment of the invention.

FIG. 4 is a schematic cross-sectional view of the organic EL device according to a second embodiment of the invention.

FIG. 5 is a schematic cross-sectional view of the organic EL device according to a third embodiment of the invention.

FIG. 6 is a schematic cross-sectional view of the organic EL device according to a fourth embodiment of the invention.

FIG. 7 is a schematic cross-sectional view of the organic EL device according to a fifth embodiment of the invention.

FIG. 8 is a schematic cross-sectional view of the organic EL device according to the fifth embodiment of the invention.

FIG. 9 is a perspective view of a mobile telephone as an electronic apparatus.

### DESCRIPTION OF EXEMPLARY EMBODIMENTS

Hereinafter, organic EL devices according to embodiments of the invention will be described with reference to the accompanying drawings. In each view used for following description, the dimensions or ratios of components are properly different from actual dimensions or ratios of the components in order that each component has a size capable of being identified in the view.

### First Embodiment

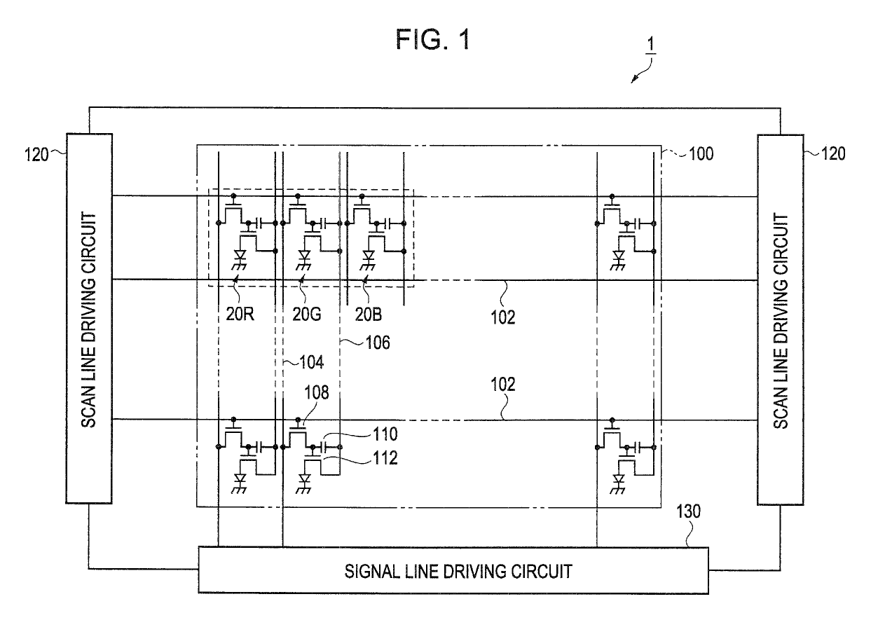

FIG. 1 is an equivalent circuit diagram of various elements, wires and the like of an organic EL device 1 as an electro-optical device according to the present embodiment. In a display region 100 of the organic EL device 1, three types of organic EL elements 20 including red organic EL elements 20R for emitting red light, green organic EL elements 20G for emitting green light, and blue organic EL elements 20B for emitting blue light are regularly arranged, which are, hereinafter, referred to as the organic EL elements 20 if emission colors are not distinguished. As described below, the organic EL elements 20 are different from each other only as an organic EL material used as an electro-optical material.

The organic EL device 1 is an active matrix type device for individually controlling the emitting of light from the organic EL elements 20 and forming an image in the display region 100 including the plurality of organic EL elements 20. In the display region 100, a plurality of scan lines 102, a plurality of signal lines 104 perpendicular to the scan lines 102, and a plurality of power supply lines 106 extending in parallel with the signal lines 104 are formed. Each of the organic EL elements 20 is formed in rectangular regions surrounded by the scan lines 102, the signal lines 104 and the power supply lines 106.

In each of the pixel regions, there is a switching thin film transistor (TFT) 108 having a gate electrode to which a scan signal is supplied via each of the scan lines 102, a storage capacitor 110 for holding a pixel signal supplied from each of the signal lines 104 via the switching TFT 108, a driving TFT 112 having a gate electrode to which the pixel signal held by the storage capacitor 110 is supplied, and an organic EL element 20 to which driving current flows from each of the power supply lines 106 via the driving TFT 112. The organic EL element 20 emits light with luminance according to the magnitude of the flowing current.

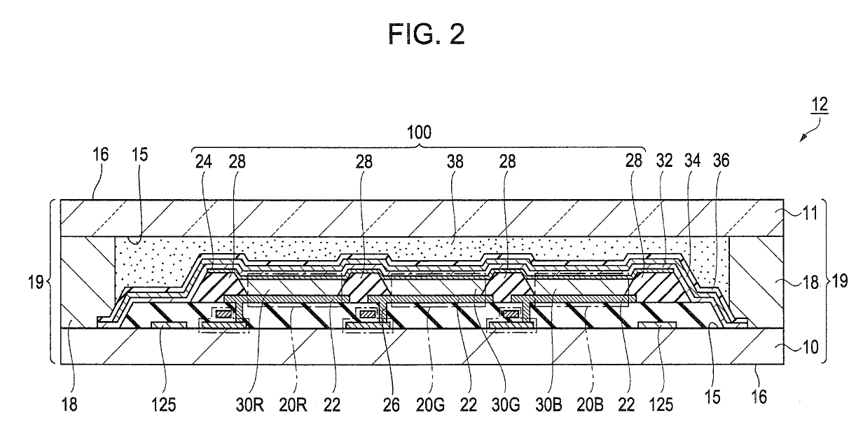

Scan line driving circuits 120 and signal line driving circuits 130 are formed at the periphery of the display region 100. The scan line driving circuits 120 sequentially supplies scan signals to the scan lines 102 according to various signals supplied from an external circuit (not shown). The signal line driving circuits 130 supplies image signals to the signal lines 104. In addition, the scan line driving circuits 120 and the signal line driving circuit 130 are collectively called a peripheral circuit 125. In addition, the peripheral circuit 125 (see FIG. 2) is connected to the external circuit (not shown).

When the scan line 102 is driven and the switching TFT 108 is turned on, the potential of the signal line 104 at that time is held by the storage capacitor 110 and the level of the driving TFT 112 is decided according to the state of the storage capacitor 110. In addition, driving current flows from the power supply line 106 to the organic EL element 20 via the driving TFT 112 and the organic EL element 20 emits light according to the magnitude of the driving current. Each of the organic EL elements 20 is independently controlled so as to adjust the emission luminance of red, green and blue in the organic EL elements 20R, 20G and 20B according to the magnitude of the driving current, thereby forming a color image in the display region 100.

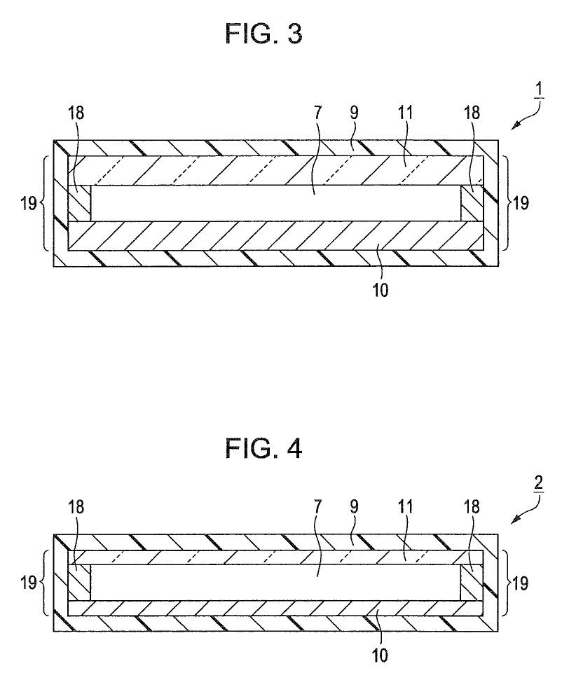

FIG. 2 is a schematic cross-sectional view of an organic EL panel as included in the organic EL device 1 (see FIG. 3) according to the present embodiment, from a direction perpendicular to a pair of substrates (a device substrate 10 and a counter substrate 11), and shows a step before a hard coat layer 9 (see FIG. 3) is formed. The electro-optical panel at such a step is called the organic EL panel 12 in the following description. Instead of the method where the organic EL panel 12 is individually formed, a method may be employed for forming a plurality of organic EL panels using a substrate having a large area, and individually dividing the organic EL panels 12 as described below.

As shown, the organic EL panel 12 includes the pair of substrates including the device substrate 10 and the counter substrate 11, and the organic EL elements 20 (in a dashed-dotted frame) sandwiched between the pair of substrates. The pair of substrates is bonded such that first surfaces 15 thereof face the organic EL elements 20 or the like, and second surfaces 16 thereof become outer surfaces. The organic EL device 1 of the present embodiment is a top emission type and an observer is located on the side of the counter substrate 11. Accordingly, it is necessary that counter substrate 11 is a substrate formed of a transparent material such as glass, but the device substrate 10 does not need to be transparent.

Each of the organic EL elements 20 includes a pair of electrodes including a cathode 24 and an anode 22, and emitting function layers 30 sandwiched between the pair of electrodes. A red emitting function layer 30R is formed in the red organic EL element 20R, a green emitting function layer 30G is formed in the green organic EL element 20G for emitting green light, and a blue emitting function layer 30B is formed in the blue organic EL element 20B for emitting blue light. The emitting function layer is a layer including an organic EL material layer for emitting light by power supply which at least includes the electro-optical material. The constituent materials of the organic EL material layers are different according to lights emitted from the organic EL elements 20. That is, the three emitting function layers 30 (R, G and B) contain different organic EL materials.

Although not shown in FIG. 2, a hole injection layer and a hole transport layer are preferably formed at the side of the anode 22 in the emitting function layers 30 and an electron injection layer and an electron transport layer are preferably formed at the side of the cathode 24. By forming such layers, it is possible to improve emission efficiency or the like.

The anode 22 is an electrode for supplying holes and is electrically independent in each of the organic EL elements 20. The cathode 24 is an electrode for supplying electrons and is formed over the entire area of the display region 100 such that the cathodes 24 of all the organic EL elements 20 have the same potential. The driving TFT (hereinafter, simply referred to as a “TFT”) is formed on the first surface 15 of the device substrate 10 in every organic EL element. In addition, in FIG. 12, the switching TFT 108 (see FIG. 1) and the storage capacitor 110 (see FIG. 1) are not shown.

An interlayer insulating layer formed of silicon oxide is formed on the upper surface of the TFT, that is, on the side of the counter substrate 11. The TFT 112 and the anode 22 are electrically connected via a contact hole 26 formed in the interlayer insulating layer. The organic EL elements are partitioned by barrier ribs 28 formed of silicon oxide or the like.

An electrode protective layer 32, an organic buffer layer 34, and a gas barrier layer 36 are sequentially laminated on the cathode 24 at the side of the counter substrate 11. The electrode protective layer 32 is a thin film formed in order to protect the cathode 24 from moisture or the like and is formed of silicon oxynitride. The organic buffer layer 34 is a thin film for reducing stress due to warping from the volume expansion of the device substrate 10 and is formed of a material having transparency and planarization function, such as an epoxy compound. The gas barrier layer 36 is a thin film for suppressing oxygen and moisture infiltration and is formed of silicon nitride or silicon oxynitride.

The counter substrate 11 and the device substrate 10 on which the gas barrier 36 is formed are bonded by an adhesive layer 38 and a seal material 18, thereby forming the organic EL panel 12. That is, the frameshaped seal material 18 is formed on the periphery of the organic EL elements 20 and the peripheral circuit 125 which is formed on the first surface 15 of the device substrate 10. The adhesive layer 38 is formed in the region surrounded by the seal material so as to cover the gas barrier layer 36, and the counter substrate 11 is bonded such that the first surface 15 of the counter substrate is brought into surface contact with the adhesive layer, thereby forming the organic EL panel 12.

A side end 19 of the organic EL panel 12 is a combination of the end surfaces of the pair of substrates and the outer circumference of the seal material 18, that is, a portion which does not face the organic EL elements 20 or the like and is not in contact with the pair of substrates. In the organic EL device 1 of the present embodiment, a hard coat layer 9 (see FIG. 3) is formed over substantially the entire surface, that is, second surfaces 16 of both of the pair of substrates configuring the organic EL panel and the above-described side end 19.

FIG. 3 is a schematic cross-sectional view of the organic EL device 1, on which the hard coat layer 9 is formed over substantially the entire surface thereof, according to the present embodiment, and is a cross-sectional view in the same direction as FIG. 2. In the present drawing and the below-described drawings, the organic EL elements 20, which are formed between the device substrate 10 and the counter substrate 11 or the like, are used as the organic EL element layer 7 which is the electro-optical material, and the detailed description thereof will be omitted. As shown, the hard coat layer 9 is formed on the entire surface of the organic EL panel 12 including the side end 19.

The hard coat layer 9 is a layer formed of a transparent material with a transmissivity of visible light of at least 85% and preferably about 98% or more. A refractive index is preferably about 1.7. Since the hard coat layer 9 is formed in order to improve the strength of the organic EL panel 12, it is preferable that the layer has a hardness equal to or more than “H” in the pencil hardness test denoted by JIS-K5400.

The thickness of the hard coat layer 9 is preferably 10 μm to 50 μm. Since cracks, which may occur in the substrates (the device substrate 10 and the counter substrate 11) during the process of dividing the organic EL panel 12, are a maximum of about 10 μm, the above-described thickness is necessary in order to fill the cracks. In the present embodiment, since the hard coat layer is formed in order to improve strength without increasing the overall thickness of the organic EL device, it is undesirable for the thickness of the hard coat layer to exceed 50 μm.

The hard coat layer 9 is formed by coating the second surfaces 16 of the substrates with a liquid material obtained by dissolving a constituent material such as resin in a solvent. As the coating method, a spin coat method is preferable when the hard coat layer is formed on the second surfaces 16. Since the spin coat method cannot be applied to the side end 19, as shown in a fifth embodiment, it is preferable that a dip method is also used.

As resin which is a constituent material of the hard coat layer 9, thermosetting or ultraviolet curing resins are preferable, in detail, polyester, polyether, acrylic resin, epoxy resin, polyurethane or the like may be used. If ultraviolet curing resin is used as the above-described resin, a mixture of a photopolymerization initiator and photosensitizer is preferably used. As the solvent, methyl ethyl ketone (MER), methyl isobutyl ketone (MIBK) or the like is preferable.

### Effect of the Present Embodiment

In the organic EL device 1 according to the present embodiment, since a sheet-shaped protective film is not bonded but the hard coat layer 9 obtained by curing the liquid material is formed on the surfaces of the substrates, cracks may be filled. Accordingly, even when the organic EL device is used in a state in which force capable of bending the organic EL device is applied, the sufficient improvement of strength can be obtained. By setting the thickness of the hard coat layer 9 to 50 μm or less, it is possible to suppress the increase in the overall thickness of the organic EL device and to prevent the hard coat layer from becoming an obstacle when the organic EL device is mounted in an electronic apparatus. Since the hard coat layer 9 is formed so as to surround the overall organic EL panel 12, the effect can be obtained for improving the strength of the side end 19. Accordingly, the organic EL device 1 according to the present embodiment can have improved strength thereof while suppressing the increase in thickness thereof and improve correspondency even when being mounted in an electronic apparatus or the like.

### Second Embodiment

Next, a second embodiment will be described. As an electro-optical device according to the present embodiment, an organic EL device 2 is substantially equal to the organic EL device 1 according to the first embodiment except for the thickness of the organic EL panel 12 (see FIG. 2). The same components as those of the organic EL device 1 are denoted by the same reference numerals and the description thereof will be omitted.

FIG. 4 is a schematic cross-sectional view of the organic EL device 2 according to the present embodiment, and is a cross-sectional view in the same direction as FIG. 3. The organic EL device 2 is characterized in that the thickness of the pair of substrates is reduced. Since the pair of substrates and, more particularly, the device substrate 10 is subjected to a process of forming the organic EL elements 20 or the like on the first surface 15, a predetermined thickness (about 0.5 mm) is necessary in order to maintain strength. However, in the organic EL device after completion, such a thickness is not necessary. In the use of the embodiment in which force is applied in the direction in which the device is bent, in order to ensure flexibility, the thickness of the substrate is preferably small. Accordingly, in the organic EL device 2 according to the present embodiment, the second surface 16 of the organic EL panel before the hard coat layer 9 is formed is subjected to an etching process or the like such that the overall thickness of the organic EL device is reduced.

The thickness of the organic EL panel 12 is preferably reduced to a thickness of 50 μm. At such a thickness, flexibility is also improved and the organic EL panel may be used in harsh conditions. In addition, the thickness of the hard coat layer 9 is preferably about 5 M. Such a thickness is advantageous when the organic EL device is mounted in an electronic apparatus, because the overall thickness of the organic EL device 2 can be suppressed to 60 μm or less. In addition, the constituent material of the hard coat layer 9 is the same as that of the organic EL device 1.

### Third Embodiment

Next, a third embodiment will be described. As an electro-optical device according to the present embodiment, an organic EL device 3 is substantially equal to the organic EL device 2 according to the second embodiment except that transparent resin particles 8 are mixed in the hard core layer. The same components as the organic EL device I and the organic EL device 2 are denoted by the same reference numerals and the description thereof will be omitted.

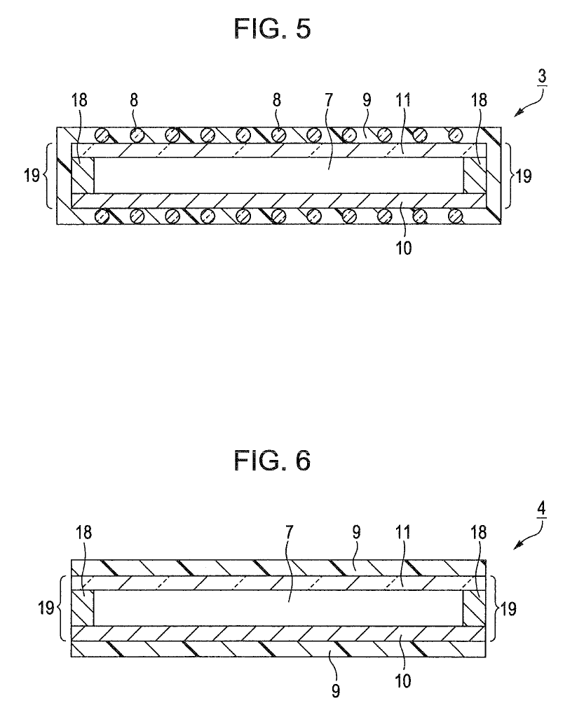

FIG. 5 is a schematic cross-sectional view of the organic EL device 3 according to the present embodiment and is a cross-sectional view in the same direction as FIG. 3. The organic EL device 3 is characterized in that the transparent resin particles 8 are mixed in the hard coat layer 9. The transparent resin particles 8 are placed in the hard coat layer 9 coated on the second surfaces 16 of the pair of substrates, but not in the hard coat layer 9 coated on the side end 19.

The transparent resin particles 8 are formed of a material different from the constituent material of the hard coat layer 9 and a refractive index thereof is 1.4 to 1.5. Although the size (diameter) of the transparent resin particles 8 seems to be substantially equal to the thickness of the hard coat layer 9 in the drawing, the size of the transparent resin particles is not limited to this size and may be smaller than the thickness of the hard coat layer 9. The size of the transparent resin particle 8 may be slightly larger than the thickness of the hard coat layer 9 and a portion of the transparent resin particles 8 may protrude out of the hard coat later 9.

The transparent resin particles 8 perform a function for suppressing the reflection of light external to the organic EL device 3 (light irradiated to the organic EL device from the outside thereof). That is, the hard coat layer 9 in which the transparent resin particles 8 are mixed functions as an external light reflection preventing layer. That is, the transparent resin particles 8 are located on the second surfaces 16 in a state of being surrounded by the hard coat layer 9 with a higher refractive index (than that of the transparent resin particles). Most of the external light incident to the transparent resin particles 8 is diffusely reflected in the transparent resin particles and is emitted over a wide area. Accordingly, the reflection ratio in a specific direction is reduced and thus external light reflection to an observer is reduced.

### Fourth Embodiment

Next, a fourth embodiment will be described. As an electrooptical device according to the present embodiment, an organic EL device 4 is substantially equal to the organic EL device 2 according to the second embodiment except for the region in which the hard coat layer is formed. The same components as the organic EL device 1 and the organic EL device 2 are denoted by the same reference numerals and the description thereof will be omitted.

FIG. 6 is a schematic cross-sectional view of the organic EL device 4 according to the present embodiment and is a cross-sectional view in the same direction as FIG. 3. The organic EL device 4 is characterized in that the hard coat layer 9 is not formed on the side end 19. If the thickness of the pair of substrates configuring the organic EL device is reduced, the strength of the organic EL device is decreased, but the structure of the side end 19 is not specially changed. Accordingly, even when the hard coat layer is formed only in the region excluding the side end 19, the above-described reduction of the strength can to some extent be compensated for.

By restricting the region in which the hard coat layer 9 is formed, the manufacturing cost of the organic EL device 4 is reduced compared with the organic EL device according to the above-described embodiments. That is, in the organic EL device 4, in addition to the reduction of the thickness, the strength is improved while suppressing the increase in the manufacturing cost.

### Fifth Embodiment

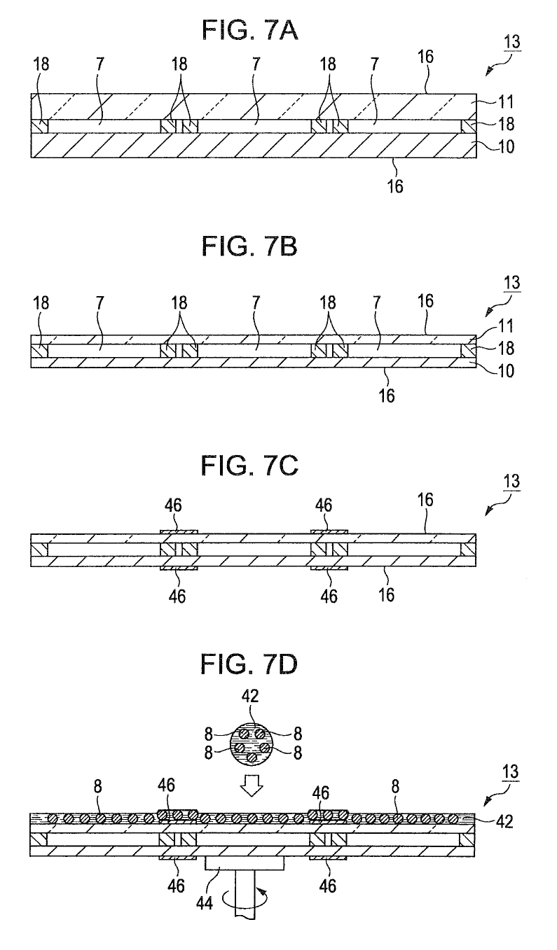

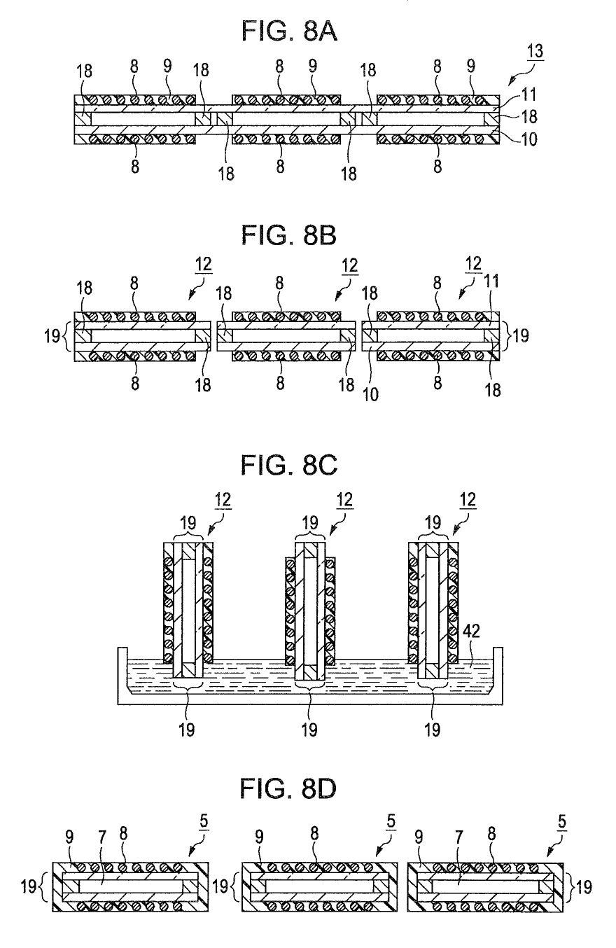

Next, as a fifth embodiment, a method of manufacturing an electro-optical device will be described with reference to the cross-sectional views shown in FIGS. 7 and 8. An organic EL device 5 which is the electro-optical device obtained by the manufacturing method of the fifth embodiment is substantially equal to the organic EL device 3.

First, as shown in FIG. 7A, an organic EL panel assembly (hereinafter, referred to as a “panel assembly”) 13 is formed by an existing method. The panel assembly 13 includes a pair of large-sized substrates (a device substrate 10 and a counter substrate 11), a plurality of organic EL element layers 7 sandwiched between the pair of substrates, and a seal material 18 formed to partition the organic EL element layer.

Next, as shown in FIG. 7B, a second surface 16 of the pair of substrates is subjected to an etching process or the like such that the thicknesses of both substrates are reduced. In addition, if an organic EL device with a predetermined thickness can be obtained, just either one out of the pair of substrates may be etched.

Next, as shown in FIG. 7C, protective tapes 46 are adhered to the second surfaces 16 of the pair of substrates. The protective tapes 46 are adhered in a predetermined width area which includes lines for dividing the panel assembly 13 in the future. As described above, the side end 19 (see FIG. 2) of the organic EL device is formed of the end surfaces of the pair of substrates and the seal material 18. Accordingly, the above-described “line dividing the panel assembly 131” is between the adjacent seal materials 18.

Next, as shown in FIG. 7D, the second surfaces 16 of the panel assembly 13 are coated with a liquid material 42 using an applying device 44. The liquid material 42 is a liquid material obtained by mixing transparent resin particles 8 in a resin which is the constituent material of a hard coat layer 9 (see FIG. 3). The liquid material 42 after coating is cured by irradiation of ultraviolet rays to form the hard coat layer 9. Such processes (coating and curing) are performed on both surfaces of the panel assembly 13.

Next, as shown in FIG. BA, the protective tapes 46 are removed. The hard coat layer 9 is formed on areas excluding both ends of the panel assembly 13 and the above-described lines dividing the panel assembly 13.

Next, as shown in FIG. 8B, the panel assembly 13 is individually divided into organic EL panels 12 by a dicing device (not shown). Due to such a process, cracks may occur in the vicinity of the side end 19.

Next, as shown in FIG. 8C, the side end 19 is coated with a liquid material 42 by a dip method. The liquid material 42 after coating is cured by ultraviolet rays or the like. By performing such a process on all four sides of the organic EL panel 12, as shown in FIG. 8D, the organic EL device 5 which includes the hard coat layer 9 in which the transparent resin particles 8 are mixed, can be obtained which is to the same as the organic EL device 3 according to the third embodiment.

According to such a manufacturing method, the organic EL device can be obtained where there is a reduction in the thickness of the pair of substrates with the organic EL element layers 7 sandwiched therebetween and suppression of the reduction of strength due to the hard coat layer 9. The reduction of strength due to cracks, which may occur during the division of the panels, can be suppressed by filling the hard coat layer 9 into the cracks. Accordingly, due to such a manufacturing method, it is possible to obtain an organic EL device where the overall device has reduced thickness and improved strength.

### Electronic Apparatus

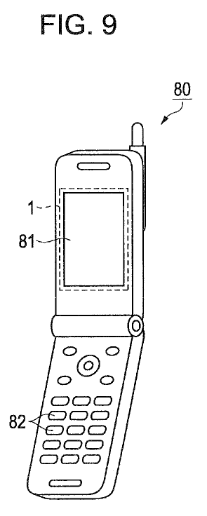

Next, an example will be described for applying any one of the organic EL devices according to the above-described first to fourth embodiments to an electronic apparatus. FIG. 9 is a perspective view of a mobile telephone 80 used as an electronic apparatus. The mobile telephone 80 has a display unit 81 and an operation button 82. The display unit 81 can display a variety of information, including contents input by the operation button 82 or incoming information, on the organic EL device 1 (or the organic EL devices 2 to 4) mounted therein.

Since the mobile telephone 80 includes the thin organic EL device, that is, the organic EL device with the overall thickness suppressed thereof according to each of the embodiments, the mobile telephone has a small size and light weight. In the above-described organic EL device, since the panel strength is enhanced by the hard coat layer 9, the strength of the mobile telephone 80 is enhanced.

### MODIFIED EXAMPLE

In the above-described embodiments, the organic EL device is described as the example of the electro-optical device. However, the embodiments of the invention are applicable to other electro-optical devices, for example, a liquid crystal device, in addition to the organic EL device. Even in the liquid crystal device, a method is generally used for simultaneously forming a plurality of liquid crystal panels using a large-sized substrate and dividing the liquid crystal panels. In such cases, by filling the hard coat layer into the cracks or the like which may occur during the division of the panels, it is possible to improve the strength of the panels.

The entire disclosure of Japanese Patent Application Not 2008-219265, filed Aug. 28, 2008 is expressly incorporated by reference herein.

What is claimed is:

1. An electro-optical device comprising:
a pair of substrates which is held to face each other with a predetermined gap therebetween; and
an electro-optical material interposed between the pair of substrates,
wherein a hard coat layer is formed on surfaces of the pair of substrates opposite to the electro-optical material.

2. The electro-optical device according to claim 1, further comprising a seal material interposed between the pair of substrates and holding the pair of substrates,
wherein the hard coat layer is formed on the end surfaces of the pair of substrates and the surfaces of the seal material opposite to the electro-optical material.

3. The electro-optical device according to claim 1, wherein the thickness of the hard coat layer is 5 μm or more and 50 μm or less.

4. The electro-optical device according to claim 1, wherein transmissivity of the hard coat layer is 85% or more.

5. The electro-optical device according to claim 1, wherein transparent resin particles, which have a refractive index lower than that of the constituent material of the hard coat layer, are mixed in the hard coat layer.

6. The electro-optical device according to claim 1, wherein the thickness of the electro-optical device excluding the hard coat layer is 50 μm to 1000 μm.

7. The electro-optical device according to claim 1, wherein the electro-optical material is an organic electroluminescence material.

8. An electronic apparatus comprising the electro-optical device according to claim 1.

9. A method of manufacturing an electro-optical device including a pair of substrates which is bonded to face each other with a predetermined gap therebetween, and an electro-optical material interposed between the pair of substrates, the method comprising:
forming an electro-optical panel by bonding one substrate to an opposing substrate with the electro-optical material sandwiched therebetween;
reducing the thickness of the electro-optical panel by polishing a second surface opposite to the first surface of at least one of the pair of substrates; and
forming a hard coat layer on the second surface of at least one of the pair of substrates.

10. The method according to claim 9, wherein:
the reducing of the thickness of the electro-optical panel includes polishing the second surfaces of both of the substrates in the pair, and
the forming of the hard coat layer includes forming the hard coat layer on the second surfaces of both of the substrates in the pair.

11. The method according to claim 9, wherein the reducing of the thickness of the electro-optical panel includes polishing the second surface such that the thickness of the electro-optical panel becomes 50 μm.

12. The method according to claim 9, wherein the forming of the hard coat layer includes forming the hard coat layer such that the thickness of the hard coat layer becomes 5 μm or more and 50 μm or less.

13. The method according to claim 9, further comprising forming the hard coat layer on the end surfaces of the electro-optical panel.

14. The method according to claim 9, wherein the forming of the hard coat layer includes forming a hard coat layer in which transparent resin particles, which have a refractive index lower than that of a constituent material of the hard coat layer, are mixed.
